(19) United States
(12) Patent Application Publication
(10) Pub. No.: US 2014/0152310 A1
(43) Pub. Date: Jun. 5, 2014

(54) GANTRY FOR MOBILIZING AN MRI DEVICE

(71) Applicant: Aspect Imaging Ltd., Shoham (IL)

(72) Inventor: Uri RAPOPORT, Moshav Ben Shemen (IL)

(21) Appl. No.: 13/939,343

(22) Filed: Jul. 11, 2013

Related U.S. Application Data
(60) Provisional application No. 61/732,353, filed on Dec. 2, 2012.

(51) Int. Cl. G01R 33/28

(52) U.S. Cl. CPC G01R 33/28
USPC 324/318; 324/300

(57) ABSTRACT

A system useful for mobilizing a magnetic resonance device (MRD) in a room. The system includes: in a room having at least one first location and at least one second remote location, comprising a structural surface, a gantry at least temporarily interconnected to the surface by a transporting mechanism; and an MRD, at least temporarily interconnected to the gantry by at least one joint. At the first and second locations, the MRD is spatially oriented in two or more different orientations. The gantry is adapted to reciprocate the MRD from the at least one first location to the at least one second remote location.

### FIELD OF THE INVENTION

The present invention relates to the field of mobilizing an MRI device. More specifically, it relates to the field of using MRI imaging in the case where the object cannot be moved to the MRI device.

### BACKGROUND OF THE INVENTION

MRI devices are of special importance in the world of medical imaging. Unlike other imaging methods, they present no radiation to the object of which they image. However, together with the benefit of no-radiation, comes the price of very large and complicated machine. In case of patients that are not able to move (e.g. premature baby in an incubator), the option of using an MRI device for scanning is practically impossible.

U.S. patent application US2007/0238950 claims a multi-modality diagnostic imaging system. The system comprises several modules which are adapted to move imaging devices in a closed space. However, the constructions of these modules depend on the location of a static patient pallet, and are oriented according to the pallet location. In addition, the construction requires the entire room to be designated for the imaging.

U.S. Pat. No. 8,118,488 claims a system for mobilizing an imaging device using a movable gantry. The device requires that the patient pallet will be located on the system. In addition the system is movable on wheels. These features of the system do not allow it to be constructed as a part of a patient room. The system needs to be delivered to it, and therefore will occupy needed space. Therefore, the system does not support the needs of easily imaging a non-movable patient.

There is therefore a long unmet need for a system which is integrated to a patient room, and allows imaging of patients without moving them.

### SUMMARY OF THE INVENTION

An object of the invention is thus to disclose a system useful for mobilizing a magnetic resonance device (MRD) in a room, the system comprising: (a) in a room having at least one first location and at least one second remote location, comprising a structural surface, a gantry at least temporarily interconnected to the surface by a transporting mechanism; and (b) an MRD, at least temporarily interconnected to the gantry by at least one joint; wherein at the first and second locations, the MRD, by means of the joint, is adapted to be spatially oriented in two or more different orientations; and wherein the gantry, by means of the transporting mechanism, is adapted to reciprocate the MRD from the at least one first location to at least one second remote location;

It is another object of the invention, to disclose the system as defined above, wherein the MRD is compact.

It is another object of the invention, to disclose the system as defined above, wherein the MRD is characterized by substantially no fringing magnetic fields, such that the MRD provides self-magnetic shielding.

It is another object of the invention, to disclose the system as defined above, wherein the MRD is by a mechanism selected from a group consisting of: manual transport mechanism, automatic manual transport mechanism, computerized manual transport mechanism, and a combination thereof.

It is another object of the invention, to disclose the system as defined above, wherein the structural surface is selected from a group consisting of: floor, ceiling, wall, a constructed surface, an artificial structuring mechanism and a combination thereof.

It is another object of the invention, to disclose the system as defined above, wherein the joint is selected from a group consisting of an articulated joint, a flexible joint, a rotatable joint, internally compensated self-aligning rotary joint, a ball joint, ball and socket joint, elbow constructed joint, hydraulic joint mechanism, telescopic joint, dampers, gimbals and claspers thereof and any combination thereof.

It is another object of the invention, to disclose the system as defined above, wherein the gantry is a modular gantry.

It is another object of the invention, to disclose the system as defined above, wherein the gantry is located in a room selected from a group consisting of: hospital room, premature special care unit, intensive care unit, neonatal unit, any space in which lies a disable object, and a combination thereof.

It is another object of the invention, to disclose the system as defined above, wherein the MRD in communication with a working station adapted to operate the MRD.

It is another object of the invention, to disclose the system as defined above, wherein the gantry additionally comprising gimbals.

It is another object of the invention, to disclose a method for mobilizing a magnetic resonance device (MRD) in a room, the method comprising steps of providing a room having at least one first location and at least one second remote location; constructing a structural surface in at least one portion of the room; at least temporarily interconnecting the gantry to the surface by means of a transporting mechanism; at least temporarily interconnecting the gantry to an MRD by means of at least one joint; at the first and second locations, spatially orienting the MRD, by means of the joint, in two or more different orientations; and transporting the MRD, by means of the transporting mechanism, from the at least one first location to at least one second remote location.

It is another object of the invention, to disclose the method as defined above, comprising step of self-magnetic shielding the MRD such that the MRD is having no fringing magnetic fields.

It is another object of the invention, to disclose the method as defined above, comprising step of selecting the step of transporting of the MRD from a group consisting of: manual transporting, automatic transporting, computerized transporting, and a combination thereof.

It is another object of the invention, to disclose the method as defined above, comprising step of selecting the structural surface from a group consisting of: floor, ceiling, wall, any constructed surface, and a combination thereof.

It is another object of the invention, to disclose the method as defined above, comprising step of constructing the gantry on a structural surface located in a room selected from a group consisting of: hospital room, premature special care unit, intensive care unit, neonatal unit, any space in which lies a disable object, and a combination thereof.

It is another object of the invention, to disclose the method as defined above, comprising step of intercommunicating between (i) the MRD; and (ii) a working station adapted to operate the MRD.

It is another object of the invention, to disclose the method as defined above, comprising step of providing the gantry with gimbals.

It is another object of the invention, to disclose the method as defined above, comprising step of selecting the joint from a group consisting of an articulated joint, a flexible joint, a rotatable joint, internally compensated self-aligning rotary joint, a ball joint, ball and socket joint, elbow constructed joint, hydraulic joint mechanism, telescopic joint, dampers, gimbals and claspers thereof and any combination thereof.

### BRIEF DESCRIPTION OF THE DRAWINGS

In order to understand the invention and to see how it may be implemented in practice, a few preferred embodiments will now be described, by way of non-limiting example only, with reference to be accompanying drawings, in which:

FIG. 1 shows one embodiment of the system for mobilizing an MRD constructed on the ceiling of a patient room;

FIG. 2 describes yet another embodiment of the current invention where the system for mobilizing an MRD is constructed on a wall of a patient room;

FIG. 3 describes yet another embodiment of the current invention where the system for mobilizing an MRD is constructed on a ceiling of an incubators' room, and where the MRD is set aside;

FIG. 4 describes yet another embodiment of the current invention where the system for mobilizing an MRD is constructed on a ceiling of an incubators' room, and where the MRD is in use, above one of the incubators;

FIG. 5 describes yet another embodiment of the current invention where the system for mobilizing an MRD is constructed on a wall of an incubators' room, and where the MRD is in use, above one of the incubators; and

FIG. 6 depicts a flow chart of a method for mobilizing an MRD device.

### DETAILED DESCRIPTION OF THE INVENTION

The following description is provided so as to enable any person skilled in the art to make use of the invention and sets forth examples contemplated by the inventor of carrying out this invention. Various modifications, however, will remain apparent to those skilled in the art, since the generic principles of the present invention have been defined specifically. Also, it is to be understood that the phraseology and terminology employed herein is for the purpose of description and should not be regarded as limiting.

One embodiment of the invention discloses a system useful for mobilizing a magnetic resonance device (MRD) in a room, the system comprising: (a) in a room having at least one first location and at least one second remote location, comprising a structural surface, a gantry at least temporarily interconnected to the surface by a transporting mechanism; and (b) an MRD, at least temporarily interconnected to the gantry by at least one joint; wherein at the first and second locations, the MRD, by means of the joint, is adapted to be spatially oriented in two or more different orientations; and wherein the gantry, by means of the transporting mechanism, is adapted to reciprocate the MRD from the at least one first location to at least one second remote location.

Another embodiment of the invention discloses a method for mobilizing a magnetic resonance device (MRD) in a room, the method comprising steps of providing a room having at least one first location and at least one second remote location; constructing a structural surface in at least one portion of the room; at least temporarily interconnecting the gantry to the surface by means of a transporting mechanism; at least temporarily interconnecting the gantry to an MRD by means of at least one joint; at the first and second locations, spatially orienting the MRD, by means of the joint, in two or more different orientations; and transporting the MRD, by means of the transporting mechanism, from the at least one first location to at least one second remote location.

Another embodiment of the invention discloses system useful for mobilizing a magnetic resonance image (MRD) device, comprising at least one gantry attached to at least one structural surface; a compact MRD interconnected to at least one gantry. The gantry is adapted to move the compact MRD in N degrees of freedom; N is a whole number larger than or equals to 1; further wherein the MRD are characterized by substantially no fringing magnetic fields, such that the MRD provides self-magnetic shielding.

Another embodiment of the invention discloses a method for mobilizing a magnetic resonance image (MRD) device, comprising steps of providing at least one gantry; attaching the gantry to at least one structural surface; interconnecting at least one gantry to a compact MRD; wherein the method additionally comprising step of moving the compact MRD in N degrees of freedom using the gantry; N is a whole number larger than or equals to 1; wherein the MRDs are characterized by substantially no fringing magnetic fields, such that the MRD provides self-magnetic shielding.

The term “gantry” refers hereinafter to a crane, or set of cranes, together with a set of modules adapted to move and operate the cranes. The modules may be rails attached to any surface on which cranes are constructed upon.

The term “gimbal” refers hereinafter to a pivoted support that allows a rotational degree of freedom to an object upon a single axis.

The term “MRD” refers hereinafter to any MRD which is constructed as a single unit, or a series of units which are not fixed in a certain location. The term also refers to portable and compact MRDs, such as a commercially available M2 MRI device by Aspect Imaging (US).

The term ‘automatic’ or ‘automatically’ refers to any process or action that proceeds without the necessity of direct action of a human being.

The term ‘manual’ or ‘manually’ refers to any process or action necessitating direct operation of a human being, either by physical work, or by operating a computerized system. For example, compact MRD may be moved by pushing it by a human being or it can be moved by operating a machine which will move it.

The term “degrees of freedom” refers to the number of independent displacements and/or rotations that specify the orientation of the body or system.

The term ‘magnetic resonance device’ (MRD) generally applies hereinafter to any analyzing, imaging or scanning device, and particularly to Nuclear Magnetic Resonance (NMR) spectroscope, Computed Tomography (CT), Computed Axial Tomography (CAT), Electron Spin Resonance (ESR) spectroscope, Nuclear Quadruple Resonance (NQR) or any combination thereof.

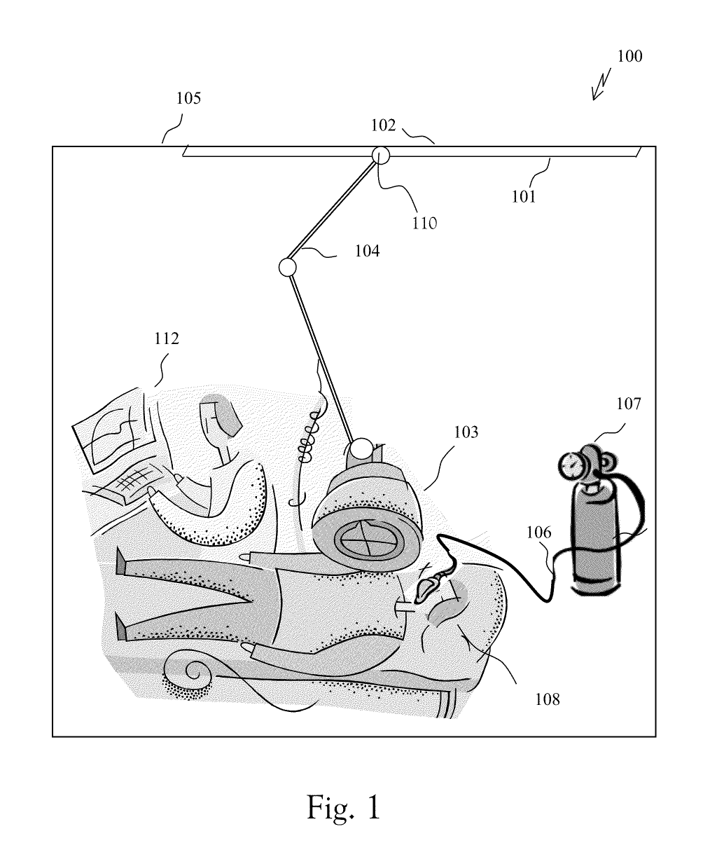

Reference is now made to FIG. 1 illustrating in a non-limiting manner a system 100 for mobilizing an MRD device 103. The system 100 comprising: at least one gantry 101 attached to at least one structural surface 102, illustrated as a ceiling; the ceiling is part of a patient's room 105; a compact MRD 103 device interconnected to at least one gantry 101; wherein the gantry 101 is adapted to move the compact MRD 103 in N degrees of freedom; N is a whole number larger than or equals to 1.

Still referring FIG. 1, a system (100) is useful for mobilizing MRI 103 in a room 105, the system comprising: (a) in a room (105) comprising a structural surface (102), a gantry (101) at least temporarily interconnected to the surface by a transporting mechanism (e.g., wheels 110); and (b) an MRD (103), at least temporarily interconnected to the gantry by at least one joint (104); wherein at least a location adjacent to a static (non-moving) patient, the MRD, by means of the joint (e.g., 110 and/or 104), is adapted to be spatially oriented in two or more different orientations; and wherein the gantry, by means of the transporting mechanism, is adapted to reciprocate the MRD from the at least one first location to at least one second remote location;

In some embodiments of the current invention, compact MRD 103 is interconnected to the at least one gantry 101 by a module 104 constructed of N joints as illustrated in FIG. 1.

Further illustrated in FIG. 1, is a patient 108, located inside the room 105, and connected via tubes 106 to some medical aid 107 (e.g. OXYGEN). The Gantry 101 will deliver the MRD 103 directly to the patient 108 and will perform the imaging without disconnecting him from any medical aid 107.

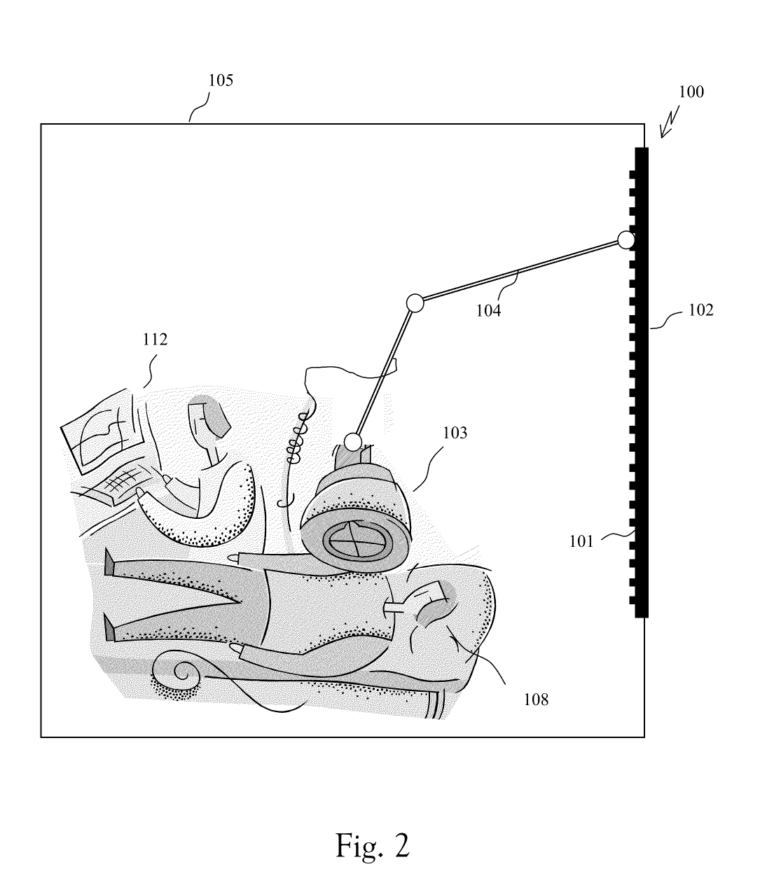

Reference is now made to FIG. 2, illustrating in a non-limiting manner another embodiment of the current invention wherein system 100 for mobilizing and MRD 103. The system 100 is constructed in a patient's 108 room 105, it comprises: (i) a gantry 101 (with 3 joints module 104), attached to the room's 105 structural surface 102, illustrated as a wall. The joints' module 104 is connected to a compact MRD 103. Wherein the gantry 101 is adapted to move the compact MRD 103 in N degrees of freedom; N is a whole number larger than or equals to 1.

Also illustrated in FIG. 2, is a computer station 112 in communication with the compact MRD 103. The computer station will have instructions for executing MRD imaging of the patient 108 without moving the patient 108.

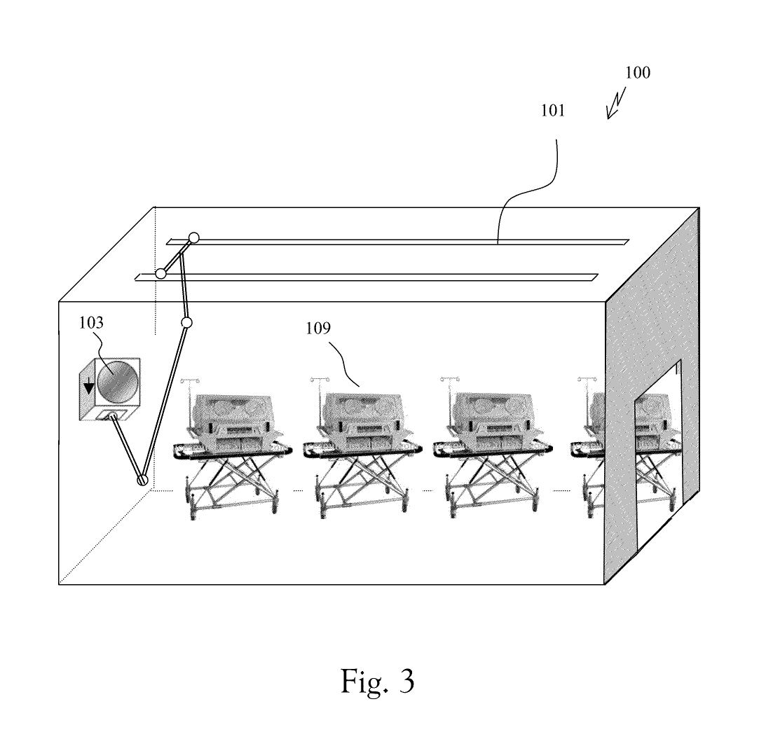

Reference is now made to FIG. 3 illustrating in a non limiting manner another embodiment of the current invention where the system (100) for mobilizing an MRD (103) is constructed on a ceiling of an incubators' room; the MRD (103) is set aside between uses. It is noted that the MRD is located here in a first location (up left) and spatially oriented in a first spatial orientation.

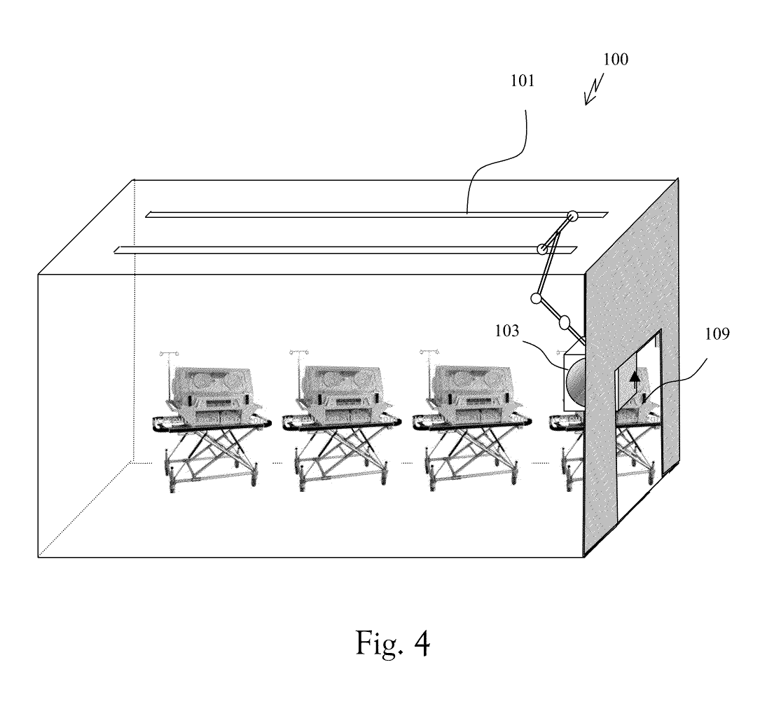

Reference is now made to FIG. 4 illustrating in a non limiting manner another embodiment of the current invention where the system (100) for mobilizing an MRD (103) is constructed on a ceiling of an incubators' room; the MRD (103) is demonstrated in use, above an incubator (109). It is further noted that the MRD is located here in a second remote location (low right) and spatially oriented in a second spatial orientation.

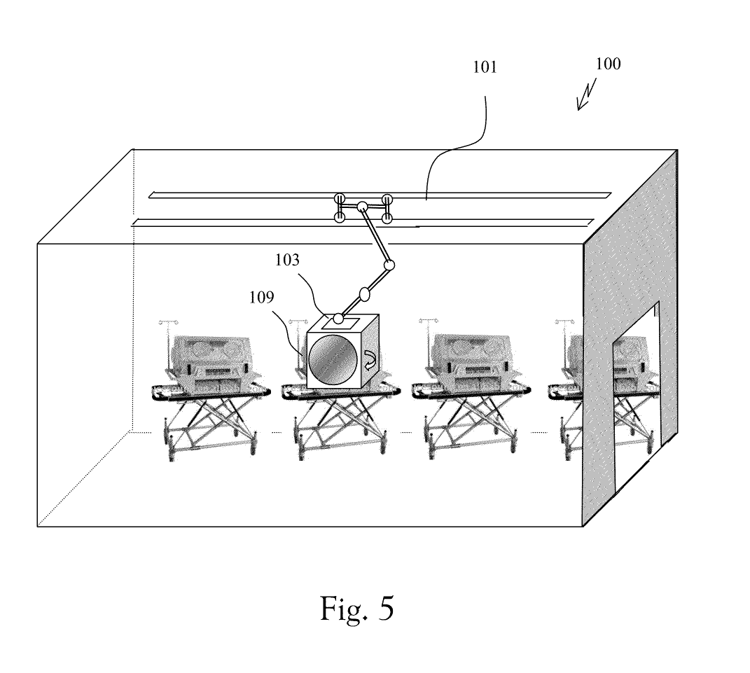

Reference is now made to FIG. 5 illustrating in a non limiting manner another embodiment of the current invention where the system (100) for mobilizing an MRD (103) is constructed on a wall of an incubators' room; the MRD (103) is demonstrated in use, above an incubator (109). It is further noted that the MRD is located here in a third remote location (middle) and spatially oriented in a third spatial (i.e., tilted-) orientation.

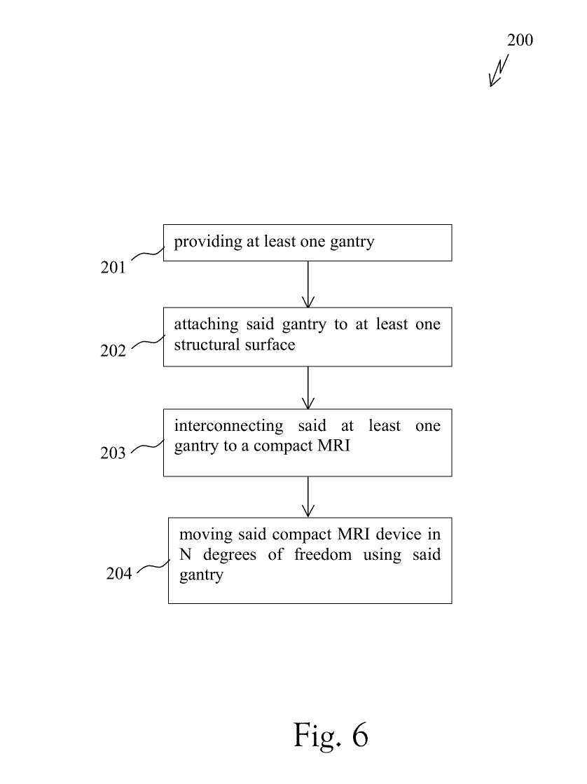

Reference is now made to FIG. 6, illustrating a flow chart of a method 200 for mobilizing a magnetic resonance image (MRD) device, the method comprising:
a. step 201 of providing at least one gantry;
b. step 202 of attaching the gantry to at least one structural surface;
c. step 203 of interconnecting at least one gantry to a compact MRD;
wherein the method additionally comprising step of:
d. step 204 of moving the compact MRD in N degrees of freedom using the gantry.

In some embodiments of the current invention, the degrees of freedom as defined above, which the gantry enables may be selected from a group consisting for example of: horizontal, longitudinal, altitudinal, angular, and a combination thereof.

In some embodiments of the current invention, movement of the compact MRD as defined above, is by a manner which may be selected from a group consisting for example of: manual, automatic, computerized, and a combination thereof.

In some embodiments of the current invention, the structural surface as defined above may be selected from a group consisting for example of: floor, ceiling, wall, any constructed surface, and a combination thereof.

In some embodiments of the current invention, compact MRD as defined above, is interconnected to at least one gantry by a module constructed of N joints. In other embodiments, a gimbal may be constructed as part of the gantry. In yet another embodiment, the gantry may be modular, enabling the removal of certain parts upon request.

In some embodiments of the current invention, the gantry as defined above, may be located in a room selected from a group consisting for example of: hospital room, premature special care unit, intensive care unit, neonatal unit, any space in which lies a disable object, and a combination thereof.

In some embodiments of the current invention, compact MRD as defined above, is in communication with a working station adapted to operate the compact MRD.

### EXAMPLE 1

In one example of the current invention, a premature is in an incubator in a special care unit. The premature needs an MRD scanning, however, moving it, is of danger to his health. In the special care unit, a gantry is constructed with a compact MRD device. The MRD can be manually moved around the rooms using rails attached to the ceiling as part of the gantry. The operator of the MRD may move the compact MRD to where the premature is placed. Once the MRD is brought to the premature location, it can be scanned without harming the premature.

### EXAMPLE 2

In another example of the current invention, a coma patient is in intensive care unit, and is respirated, therefore he cannot be moved from his bed. A gantry is constructed on the wall of the patient room and an MRD is attached to the gantry. An operator is sitting in another location, and by using a computer system, he is able to access the gantry for mobilizing the MRD to the patient. The operator may also have the possibility of operating the MRD using his computer system in order to image the patient.

It will be appreciated by persons skilled in the art that embodiment of the invention are not limited by what has been particularly shown and described hereinabove. Rather the scope of at least one embodiment of the invention is defined by the claims below.

1. A system useful for mobilizing a magnetic resonance device (MRD) in a room, the system comprising:
(i) in a room having at least one first location and at least one second remote location, comprising a structural surface, a gantry at least temporarily interconnected to said surface by a transporting mechanism; and
(ii) an MRD, at least temporarily interconnected to said gantry by at least one joint, wherein at said first and second locations, said MRD, by means of said joint, is adapted to be spatially oriented in two or more different orientations; and wherein said gantry, by means of said transporting mechanism, is adapted to reciprocate said MRD from said at least one first location to at least one second remote location.

2. The system according to claim 1, wherein said MRD is characterized by substantially no fringing magnetic fields, such that said MRD provides self-magnetic shielding.

3. The system according to claim 1, wherein said transport of said MRD is by a mechanism selected from a group consisting of: manual transport mechanism, automatic manual transport mechanism, computerized manual transport mechanism, and a combination thereof.

4. The system according to claim 1, wherein said structural surface is selected from a group consisting of: floor, ceiling, wall, a constructed surface, an artificial structuring mechanism and a combination thereof.

5. The system according to claim 1, wherein joint is selected from a group consisting of an articulated joint, a flexible joint, a rotatable joint, internally compensated self-aligning rotary joint, a ball joint, ball and socket joint, elbow constructed joint, hydraulic joint mechanism, telescopic joint, dampers, gimbals and claspers thereof and any combination thereof.

6. The system according to claim 1, wherein said gantry is a modular gantry.

7. The system according to claim 1, wherein said gantry is located in a room selected from a group consisting of: hospital room, premature special care unit, intensive care unit, neonatal unit, any space in which lies a disable object, and a combination thereof.

8. The system according to claim 1, wherein said MRD in communication with a working station adapted to operate said MRD.

9. The system according to claim 1, wherein said gantry additionally comprising gimbals.

10. A method for mobilizing a magnetic resonance device (MRD) in a room, the method comprising:
(i) providing a room having at least one first location and at least one second remote location;
(ii) constructing a structural surface in at least one portion of said room
(iii) at least temporarily interconnecting said gantry to said surface by means of a transporting mechanism;
(iv) at least temporarily interconnecting said gantry to an MRD by means of at least one joint;
(v) at said first and second locations, spatially orienting said MRD, by means of said joint, in two or more different orientations; and
(vi) transporting said MRD, by means of said transporting mechanism, from said at least one first location to at least one second remote location.

11. The method according to claim 10, providing said MRD with self-magnetic shielding such that said MRD is having no fringing magnetic fields.

12. The method according to claim 10, additionally comprising step of selecting said step of transporting of said MRD from a group consisting of: manual transporting, automatic transporting, computerized transporting, and a combination thereof.

13. The method according to claim 10, additionally comprising step of selecting said structural surface from a group consisting of: floor, ceiling, wall, any constructed surface, and a combination thereof.

14. The method according to claim 10, additionally comprising step of constructing said gantry on a structural surface located in a room selected from a group consisting of: hospital room, premature special care unit, intensive care unit, neonatal unit, any space in which lies a disable object, and a combination thereof.

15. The method according to claim 10, additionally comprising step of intercommunicating between (i) said MRD; and (ii) a working station adapted to operate said MRD.

16. The method according to claim 10, additionally comprising step of providing said gantry with gimbals.

17. The method according to claim 10, additionally comprising step of selecting said joint from a group consisting of an articulated joint, a flexible joint, a rotatable joint, internally compensated self-aligning rotary joint, a ball joint, ball and socket joint, elbow constructed joint, hydraulic joint mechanism, telescopic joint, dampers, gimbals and claspers thereof and any combination thereof.
